(19) United States
(12) Patent Application Publication
(10) Pub. No.: US 2009/0075210 A1
(43) Pub. Date: Mar. 19, 2009

(54) EXPOSURE APPARATUS AND METHOD OF MANUFACTURING DEVICE

(75) Inventors: Atsushi Takagi, Utsunomiya-shi (JP); Yoshio Kawanobe, Utsunomiya-shi (JP)

Correspondence Address: MORGAN & FINNEGAN, L.L.P., 3 WORLD FINANCIAL CENTER, NEW YORK, NY, 10281-2101, US

(73) Assignee: CANON KABUSHIKI KAISHA, Tokyo (JP)

(21) Appl. No.: 12/208,423

(22) Filed: Sep. 11, 2008

(30) Foreign Application Priority Data
Sep. 14, 2007 (JP) 2007-240178

(51) Int. Cl. G03F 7/20; G03B 27/68

(52) U.S. Cl. 430/311; 355/52

(57) ABSTRACT

An exposure apparatus which includes a projection optical system configured to project light from an original onto a substrate and performs an exposure of the substrate to light via a liquid that fills a gap between a final optical element of the projection optical system and the substrate, the apparatus comprises a controller configured so that 1) an exposure condition for the substrate is input to the controller, the exposure condition including a shot area layout and a dose for a shot area, and 2) the controller obtains a contact time during which the shot area is to be kept in contact with the liquid based on the input exposure condition, and corrects the input dose based on the obtained contact time.

### BACKGROUND OF THE INVENTION

1. Field of the Invention

The present invention relates to an exposure apparatus and a method of manufacturing a device.

2. Description of the Related Art

When a semiconductor device, a liquid crystal display device, a thin-film magnetic head, or the like is to be manufactured in a lithography process, a semiconductor exposure apparatus is used, which forms a latent image on a photoresist coated on a substrate by projecting a circuit pattern on a reticle via a projection optical system.

With a decrease in the size of the circuit patterns of devices and an increase in packing density, a projection exposure apparatus for semiconductor manufacture is required to transfer patterns on reticles at high resolutions. A resolution is based on the numerical aperture (NA) of a projection optical system and the wavelength of exposure light. That is, the resolution increases as the NA increases and the wavelength of exposure light decreases.

With regard to the shortening of wavelengths, a technique of shortening the wavelength of light generated by a light source has been studied. With this study, the wavelength of exposure light tends to decrease from 248 nm, which is the oscillation wavelength of a KrF excimer laser, to 193 nm, which is the oscillation wavelength of an ArF excimer laser.

With regard to an increase in numerical aperture (NA), a projection exposure technique using an immersion method has attracted a great deal of attention. The immersion method has originally been proposed to increase the resolution of an optical microscope. According to this technique, the space between a lens and a sample is filled with a liquid having a refractive index greater than 1.

WO99/49504 has proposed an exposure apparatus using this immersion method, i.e., an immersion exposure apparatus.

Consider a case in which the gap between the final optical element of a projection optical system and a substrate is filled with ultrapure water having a refractive index of 1.44 as a liquid. Assuming that the maximum incident angle of light on a wafer remains unchanged, the NA obtained when a light beam passes through ultrapure water is 1.44 times that obtained when the gap is filled with a gas. According to the Rayleigh equation, the resolution increases by 1.44 times. This makes it possible to obtain a resolution of NA>1.

In an immersion exposure apparatus, the photoresist coated on a substrate comes into contact with the liquid, and hence causes a reaction with the liquid. This may change the characteristics of the photoresist. That is, the chemical characteristics of the photoresist with respect to a developing solution may change depending on the contact time with the liquid. It is therefore possible that the line width of a latent image pattern formed on the photoresist, i.e., the CD (Critical Dimension), will vary.

For example, the immersion method uses an ArF laser as a light source, and also uses a chemically amplified resist as a photoresist. When exposure light is applied to a chemically amplified resist, the resist produces an acid. The produced acid is heated and acts as a catalyst which causes many chemical reactions. This catalytic reaction changes the solubility of a chemically amplified resist with respect to the developing solution. This makes it possible to form a pattern. At this time, if the liquid which is made to come into contact with the photoresist contains a component which deactivates the acid, e.g., ammonia, the acid produced by the photoresist upon exposure to light is deactivated, resulting in loss of solubility with respect to the developing solution. As a result, the line width of an obtained pattern may vary depending on the contact times of the photoresist with the liquid.

For example, in the immersion method, the photoresist which comes into contact with the liquid sometimes absorbs the liquid. As a result, the sensitivity of the photoresist with respect to the amount of exposure light varies. It is therefore possible that the line width of an obtained pattern will vary depending on the contact time of the photoresist with the liquid.

In order to solve these problems, resist makers have developed top coats to be coated as passivation films on resists. However, a liquid may pass through a top coat, and a complicated step is required to remove the top coat in developing operation, resulting in an increase in cost. For these reasons, it is required to use only a conventional photoresist without using any top coat.

### SUMMARY OF THE INVENTION

The present invention provides for reducing variation in a line width of a pattern.

According to first aspect of the present invention, an exposure apparatus which includes a projection optical system configured to project light from an original onto a substrate and performs an exposure of the substrate to light via a liquid that fills a gap between a final optical element of the projection optical system and the substrate, the apparatus comprises a controller configured so that 1) an exposure condition for the substrate is input to the controller, the exposure condition including a shot area layout and a dose for a shot area, and 2) the controller obtains a contact time during which the shot area is to be kept in contact with the liquid based on the input exposure condition, and corrects the input dose based on the obtained contact time.

According to a second aspect of the present invention, a method of manufacturing a device comprises: exposing a substrate to light using the exposure apparatus according to the first aspect of the present invention; developing the exposed substrate; and processing the developed substrate to manufacture the device.

According to the present invention, variation in a line width of a pattern can be reduced.

Further features of the present invention will become apparent from the following description of exemplary embodiments with reference to the attached drawings.

### BRIEF DESCRIPTION OF THE DRAWINGS

FIG. 1 is a view showing the arrangement of an exposure apparatus 100 according to an embodiment of the present invention;

FIG. 2 is a flowchart showing a preparation processing procedure for exposure processing using the exposure apparatus 100;

FIG. 3 is a flowchart showing a processing procedure for exposure processing using the exposure apparatus 100;

FIG. 4 is a graph showing information of a first function;

FIG. 5 is a graph showing information of a second function;

FIG. 6 is a flowchart showing a processing procedure at the time of decision of a cleaning schedule for the exposure apparatus 100;

FIG. 7 is a graph showing information of a third function;

FIG. 8 is a graph showing information of a fourth function;

FIG. 9 is a view showing a substrate in a modification of the embodiment of the present invention; and

FIG. 10 is a view showing a substrate in a modification of the embodiment of the present invention.

### DESCRIPTION OF THE EMBODIMENTS

The present invention relates to a semiconductor exposure apparatus which is used when, for example, a semiconductor device, a liquid crystal display device, or a thin-film magnetic head is to be manufactured in a lithography process and, more particularly, to an exposure apparatus using an immersion method (to be referred to as an immersion exposure apparatus hereinafter).

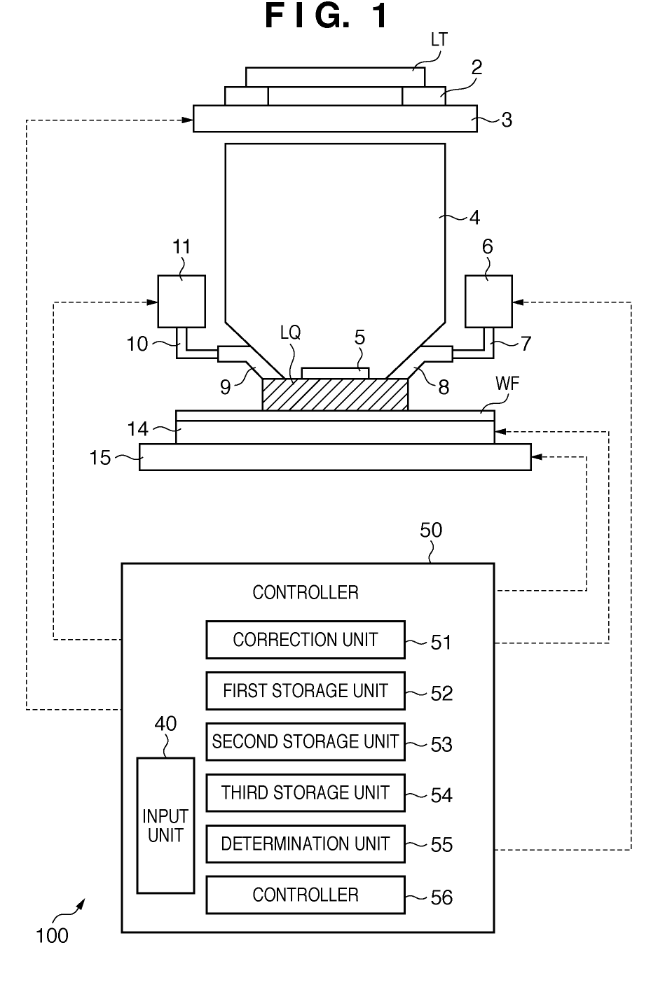

An exposure apparatus 100 according to an embodiment of the present invention will be described with reference to FIG. 1. FIG. 1 is a view showing the arrangement of the exposure apparatus 100 according to an embodiment of the present invention.

The exposure apparatus 100 comprises an illumination optical system (not shown), an original stage 2, an original stage platen 3, a projection optical system 4, a liquid supply apparatus 6, a supply pipe 7, a liquid supply nozzle 8, a liquid recovery nozzle 9, a recovery pipe 10, and a liquid recovery apparatus 11. The exposure apparatus 100 comprises a substrate stage 14, a substrate stage platen 15, and a controller 50.

The illumination optical system (not shown) receives light emitted from a light source (not shown) such as an ArF excimer laser and applies the light to an original LT. An original is also referred to as a mask or a reticle.

The original stage 2 holds the original LT. The original LT is, for example, a reticle. A predetermined pattern is formed on the original LT by using Cr or the like.

The original stage platen 3 holds the original stage 2. The controller 50 drives/controls the original stage 2 so as to position the original LT via the original stage 2.

The projection optical system 4 reduces and projects the light diffracted by the pattern on the original LT onto a substrate WF. The projection optical system 4 includes a plurality of optical elements. In this case, an optical element, of the plurality of optical elements included in the projection optical system 4, which is located on the most downstream side (image plane side) on an optical axis will be referred to as a final optical element 5.

The liquid supply apparatus 6 supplies a liquid LQ from the liquid supply nozzle 8 to the gap between the final optical element 5 and the substrate WF via the supply pipe 7. With this operation, a light beam passing through the projection optical system 4 reaches the substrate WF via the liquid LQ for immersion, and the pattern is transferred onto the photoresist coated on the substrate WF. The liquid recovery nozzle 9 recovers the liquid LQ for immersion. This liquid is recovered into the liquid recovery apparatus 11 via the recovery pipe 10.

The substrate stage 14 holds the substrate WF. The substrate WF is, for example, a wafer. The substrate WF is coated with a photoresist. The controller 50 drives/controls the substrate stage 14 to position the substrate WF via the substrate stage 14.

The substrate stage platen 15 holds the substrate stage 14.

The controller 50 includes an input unit 40, a correction unit 51, a first storage unit 52, a second storage unit 53, a third storage unit 54, a determination unit 55, and a controller 56.

A user inputs a predetermined instruction to the input unit 40. The user inputs an exposure condition (recipe) for the substrate WF to the input unit 40 in advance before the execution of exposure processing. The exposure condition for the substrate WF includes, for example, information associating the amount of exposure light and illuminance for each shot area with an exposure layout (the coordinates of the shot areas and the like) and an exposure schedule for the respective shot areas. The input unit 40 supplies the information of the exposure condition for the substrate WF to the first storage unit 52.

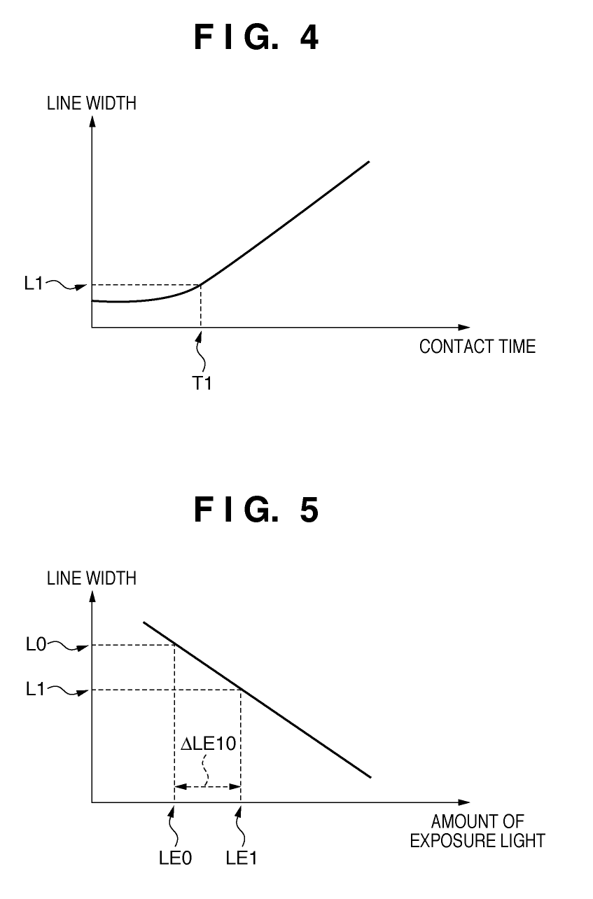

The correction unit 51 receives the information of the exposure condition for the substrate WF from the first storage unit 52, and obtains the contact time during which each shot area of the substrate WF is kept in contact with the liquid LQ on the basis of the exposure condition for the substrate WF. The correction unit 51 obtains the predicted line width of a pattern in each shot area on the basis of the contact time of the shot area, and corrects the amount of exposure light for the shot area on the basis of the predicted line width. More specifically, the correction unit 51 obtains the predicted line width for each shot area on the basis of the contact time and information of the first function (see FIG. 4). The information of the first function is the information on a function indicating the relationship between the time during which each shot area is kept in contact with the liquid and the line width of an obtained pattern. The correction unit 51 obtains a correction value for the amount of exposure light for each shot area on the basis of the predicted line width, a target line width, and the second function information (see FIG. 5). The second function information is the information of a function indicating the relationship between the line width of an obtained pattern and the amount of exposure light for obtaining the line width. That is, the correction unit 51 corrects the amount of exposure light for each shot area on the basis of the contact time of the shot area.

The first storage unit 52 receives the information of the exposure condition for the substrate WF from the input unit 40. The exposure condition for the substrate WF includes, for example, information associating the amount of exposure light and illuminance for each shot area with an exposure layout (the coordinates of the shot areas and the like) and an exposure schedule for the respective shot areas. The first storage unit 52 stores the exposure condition for the substrate WF.

The second storage unit 53 stores the first function information (see FIG. 4). The first function information is the information of a function indicating the relationship between the time during which each shot area is kept in contact with the liquid and the line width of an obtained pattern. FIG. 4 is a graph showing information of the first function.

The third storage unit 54 stores information of the second function (see FIG. 5). The information of the second function is the information of a function indicating the relationship between the line width of an obtained pattern and the amount of exposure light for obtaining the line width. FIG. 5 is a graph showing the information of the second function.

The determination unit 55 obtains a cleaning cycle for the final optical element 5 on the basis of the exposure condition for the substrate WF which is stored in the first storage unit 52. The determination unit 55 obtains the accumulated time during which the final optical element 5 is kept in contact with the liquid LQ after cleaning on the basis of the exposure schedule designated in the exposure condition for the substrate WF and information indicating an immediately preceding cleaning timing. The determination unit 55 decides a cleaning schedule for the final optical element 5 on the basis of the accumulated time and the cleaning cycle.

The controller 56 controls the input unit 40, correction unit 51, first storage unit 52, second storage unit 53, third storage unit 54, and determination unit 55.

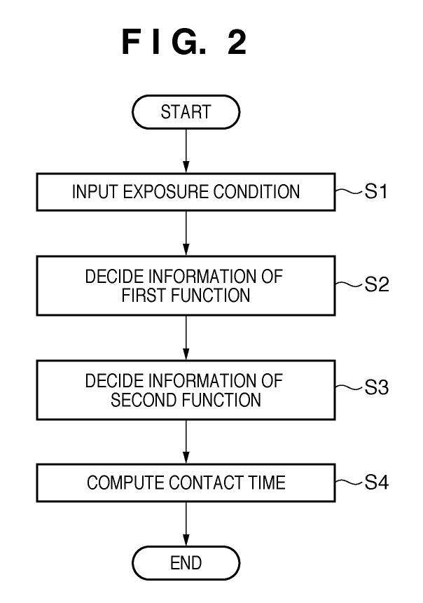

A preparation processing procedure for exposure processing using the exposure apparatus 100 will be described next with reference to FIG. 2. FIG. 2 is a flowchart showing the preparation processing procedure for exposure processing using the exposure apparatus 100.

In step S1, an exposure condition for the substrate WF and a set instruction are input to the input unit 40. The controller 56 receives the information of the exposure condition for the substrate WF and the set instruction from the input unit 40, and causes the first storage unit 52 to store the information of the exposure condition for the substrate WF in accordance with the set instruction. The exposure condition for the substrate WF includes, for example, information associating the amount of exposure light and illuminance for each shot area with an exposure layout (the coordinates of the shot areas and the like) and an exposure schedule for the respective shot areas.

In step S2, information of the first function is decided. The information of the first function is the information of a function indicating the relationship between the time during which each shot area is kept in contact with the liquid LQ and the line width of an obtained pattern. The information of the first function is obtained by an experiment using test patterns.

That is, the user prepares a plurality of samples and forms test patterns (latent image patterns) on the samples by exposing the samples to light using the exposure apparatus 100 while changing the time during which each sample is kept in contact with the liquid LQ. In this case, the time during which each sample is kept in contact with the liquid LQ is changed to make the amount of exposure light for each sample constant. The user performs PEB (Post Exposure Bake) and development for the test pattern on each sample, and then measures the line width of the test pattern formed on each sample by using a CD measuring device such as a scattering measurement device or SEM. In this case, the time from exposure to development, i.e., the PED (Post Exposure Development) time, influences the image performance, and hence is made constant for each sample. In this manner, the user inputs the data of the times during which the samples are kept in contact with the liquid LQ and CD measurement results concerning the respective samples to a computer (not shown). With this operation, the computer plots the relationship between the times during which the samples are kept in contact with the liquid LQ and the CD measurement results, and makes an approximation with a function or the like, thereby obtaining the relationship as a function. With this operation, the computer decides the information of the first function shown in FIG. 4.

The user reads out the information of the first function from the computer and inputs it to the input unit 40 of the exposure apparatus 100. The second storage unit 53 of the controller 50 receives the information of the first function from the input unit 40 and stores it.

In step S3, information of the second function is decided. The information of the second function is the information on a function indicating the relationship between the line width of an obtained pattern and the amount of exposure light for obtaining the line width. The second function information is obtained in advance by an experiment using test patterns.

That is, the user prepares a plurality of samples and forms test patterns (latent image patterns) on the samples by exposing the samples to light using the exposure apparatus 100 while changing the amount of exposure light. The user performs PEB (Post Exposure Bake) and development for the test pattern on each sample, and then measures the line width of the test pattern formed on each sample by using a CD measuring device such as a scattering measurement device or SEM. In this case, the time from exposure to development, i.e., the PED (Post Exposure Development) time, influences the image performance, and hence is made constant for each sample. In this manner, the user inputs the data of the amounts of exposure light and CD measurement results concerning the respective samples to the computer (not shown). With this operation, the computer plots the relationship between the amounts of exposure light and the CD measurement results, and makes an approximation with a quartic function or the like, thereby obtaining the relationship as a function. With this operation, the computer decides the information of the second function shown in FIG. 5.

The user reads out the information of the second function from the computer and inputs it to the input unit 40 of the exposure apparatus 100. The third storage unit 54 of the controller 50 receives the information of the second function from the input unit 40 and stores it.

In step S4, the contact time for each shot area is calculated. The contact time for each shot area is calculated on the basis of the exposure condition set in step S1.

That is, the user reads out the information of the exposure condition for the substrate WF from the first storage unit 52 of the controller 50 and inputs it to the computer (not shown). With this operation, the computer computes the exposure time per slit (see equation 1) for each shot area on the basis of the exposure condition.

$$\begin{matrix}( exposure time per slit ) = ( slit width ) / ( scan speed ) \\ = ( illuminance ) / ( amount of exposure light )\end{matrix}$$

The computer then computes the contact time of each shot area on the basis of the exposure condition in consideration of the time during which each shot area is kept in contact with the liquid LQ while the shot area is not exposed to light.

The user reads out the information of the contact time of each shot area from the computer and inputs it to the input unit 40 of the exposure apparatus 100. The first storage unit 52 of the controller 50 receives the information of the contact time of each shot area from the input unit 40 and stores it.

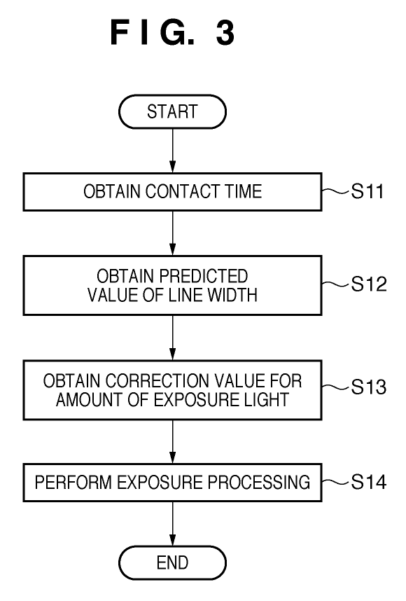

A processing procedure for exposure processing using the exposure apparatus 100 will be described with reference to FIG. 3. FIG. 3 is a flowchart showing a processing procedure for exposure processing using the exposure apparatus 100.

In step S11, the input unit 40 of the controller 50 receives a start instruction for starting exposure processing from the user and transfers it to the controller 56. The controller 56 controls the correction unit 51 in accordance with the start instruction. With this operation, the correction unit 51 accesses the first storage unit 52 and acquires the information of the contact time of each shot area as an exposure target. The information of the contact time of each shot area is computed on the basis of the exposure condition for the substrate WF. That is, the correction unit 51 obtains the contact time of each shot area as an exposure target on the basis of the exposure condition for the substrate WF.

In the case shown in FIG. 4, for example, the correction unit 51 obtains a contact time T1 of each shot area as an exposure target.

In step S12, the correction unit 51 accesses the second storage unit 53 and acquires the information of the first function (see FIG. 4). The correction unit 51 obtains the predicted line width on the basis of the contact time of each shot area and the information of the first function.

In the case shown in FIG. 4, for example, the correction unit 51 obtains a predicted line width L1 corresponding to the contact time T1 of each shot area by referring to the information of the first function.

In step S13, the correction unit 51 accesses the third storage unit 54 and acquires the second function information (see FIG. 5). The correction unit 51 accesses the first storage unit 52 and acquires the information of a target line width included in the exposure condition for the substrate WF. The correction unit 51 obtains a correction value for the amount of exposure light for each short area as an exposure target on the basis of the predicted line width, the target line width, and the second function information.

In the case shown in FIG. 5, for example, the correction unit 51 obtains an amount LE1 of exposure light corresponding to the predicted line width L1 by referring to the information of the second function. The correction unit 51 obtains an amount LE0 of exposure light corresponding to a target line width L0 by referring to the information of the second function. The correction unit 51 then obtains a correction value for the amount of exposure light ΔLE10 (see equation 2) for each shot area as an exposure target on the substrate WF.

ΔLE10=LE0−LE1 (2)

In step S14, the correction unit 51 accesses the first storage unit 52 and acquires the information of the exposure condition for the substrate WF. The correction unit 51 corrects the amount of exposure light for each shot area designated by the exposure condition for the substrate WF by using the correction value obtained in step S13. The correction unit 51 supplies the information of the amount of exposure light for the shot area after correction to the controller 56. The controller 56 performs exposure processing for the shot area with the amount of exposure light for the shot area after correction.

The correction unit 51 corrects the amount of exposure light for the shot area on the basis of the contact time of the shot area on the substrate WF. With this operation, the line width of the obtained pattern can be made close to the target line width L0. That is, when the substrate WF is exposed to light via the liquid LQ filling the gap between the final optical element 5 of the projection optical system 4 and the substrate WF, variations in the line width of a pattern can be reduced.

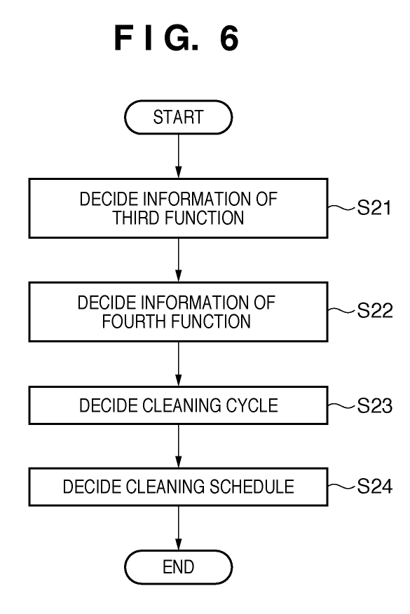

A processing procedure for the decision of a cleaning schedule for the exposure apparatus 100 will be described next with reference to FIG. 6. FIG. 6 is a flowchart showing a processing procedure for the decision of a cleaning schedule for the exposure apparatus 100.

In step S21, information of the third function is decided. The information of the third function is the information of a function indicating the relationship between the amount of deposit (deposit amount) on the final optical element 5 of the projection optical system 4 and illuminance irregularity on the substrate WF. The information of the third function is obtained by an experiment.

That is, the user prepares a plurality of samples, and exposes each sample to light while keeping the sample in contact with the liquid LQ for a predetermined period of time. The user measures the amount of deposit on the final optical element 5 of the projection optical system 4 every time exposure finishes. The user also measures illuminance irregularity on the substrate WF. In this manner, the user inputs the data of the deposit amount and illuminance irregularity to the computer (not shown) every time exposure finishes. With this operation, the computer plots the relationship between the deposit amount and the illuminance irregularity, and makes an approximation with a quartic function or the like, thereby obtaining the relationship as a function. With this operation, the computer decides the information of the third function shown in FIG. 7. FIG. 7 shows the information of the third function.

The user reads out the information of the third function from the computer and inputs it to the input unit 40 of the exposure apparatus 100. The second storage unit 53 of the controller 50 receives the information of the third function from the input unit 40 and stores it.

In step S22, information of the fourth function is decided. The information of the fourth function is the information of a function indicating the relationship between the amount of deposit (deposit amount) on the final optical element 5 of the projection optical system 4 and the accumulated time during which the final optical element 5 is kept in contact with the liquid LQ after cleaning. The fourth function information is obtained by an experiment.

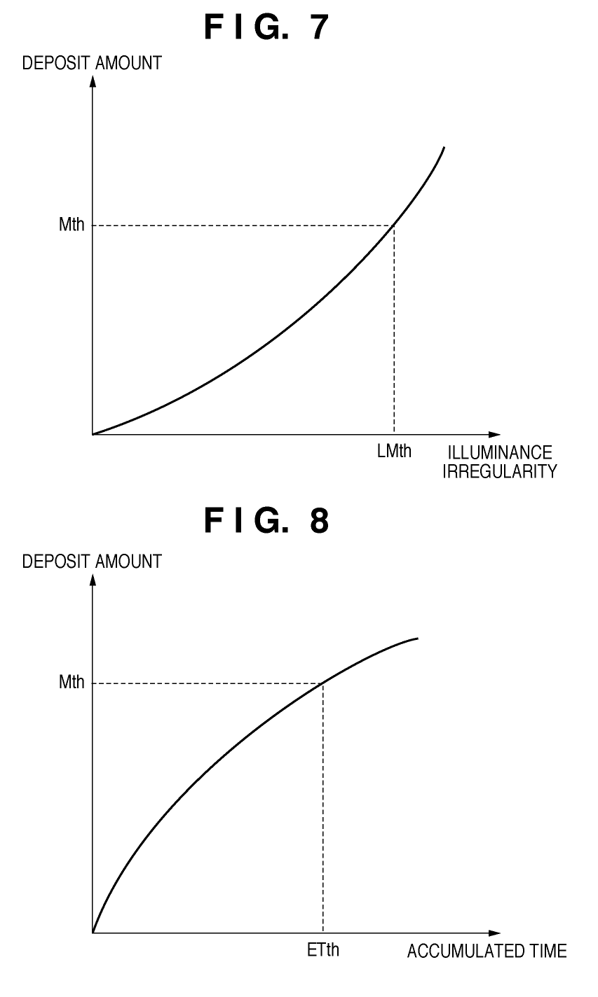

That is, the user prepares a plurality of samples, and cleans the final optical element 5 in advance. The user exposes each sample to light for a predetermined period of time. The user measures the amount of deposit on the final optical element 5 of the projection optical system 4 every time exposure finishes. In this manner, the user inputs the data of the deposit amount and exposure time to the computer (not shown) every time exposure finishes. With this operation, the computer obtains the accumulated time by totalizing the exposure times. The computer then plots the relationship between the deposit amount and the accumulated time, and makes an approximation with a quartic function or the like, thereby obtaining the relationship as a function. With this operation, the computer decides the information of the fourth function shown in FIG. 8. FIG. 8 shows the information of the fourth function.

The user reads out the fourth function information from the computer and inputs it to the input unit 40 of the exposure apparatus 100. The second storage unit 53 of the controller 50 receives the information of the fourth function from the input unit 40 and stores it.

In step S23, the input unit 40 receives the information of the required allowable value of illuminance irregularity. In this case, the required allowable value of illuminance irregularity is the value determined by the specifications of the exposure apparatus 100. The controller 56 receives the information of the required allowable value of illuminance irregularity from the input unit 40 and controls the determination unit 55. The determination unit 55 receives the information of the required allowable value of illuminance irregularity from the controller 56 and accesses the second storage unit 53 to acquire the information of the third function and the information of the fourth function. The determination unit 55 decides a cleaning cycle on the basis of the required allowable value of illuminance irregularity.

In the case shown in FIGS. 7 and 8, for example, the determination unit 55 obtains a threshold Mth for a deposit amount corresponding to a required allowable value LMth of illuminance irregularity by referring to the information of the third function. The determination unit 55 then determines a cleaning cycle ETth corresponding to the threshold Mth of a deposit amount by referring to the fourth function information.

In step S24, the determination unit 55 accesses the first storage unit 52 and acquires the information of the exposure condition for the substrate WF which includes an exposure schedule. The determination unit 55 also acquires information indicating an immediately preceding cleaning timing from the first storage unit 52. The determination unit 55 obtains the accumulated time during which the final optical element 5 is kept in contact with the liquid LQ after cleaning of the final optical element 5 on the basis of exposure schedule and the immediately preceding cleaning timing. The determination unit 55 then decides a cleaning schedule for the final optical element 5 on the basis of the cleaning timing and the accumulated time. This makes it possible to clean the final optical element 5 in a proper period without excessively decreasing the throughput of the exposure apparatus 100.

Note that cleaning is performed while ozone water or surfactant is kept in contact with the final optical element 5. It suffices to obtain the above accumulated time on the basis of the timing at which the liquid LQ is supplied from the liquid supply nozzle 8 and the timing at which the liquid LQ is recovered from the liquid recovery nozzle 9. For example, the controller 56 of the controller 50 causes a timer (not shown) to start counting an accumulated time from the timing at which the controller starts supplying a command to supply the liquid LQ to the liquid supply apparatus 6. The controller 56 of the controller 50 then causes the timer to finish counting the accumulated time at the timing at which the controller finishes supplying a command to finish recovering the liquid LQ to the liquid recovery apparatus 11.

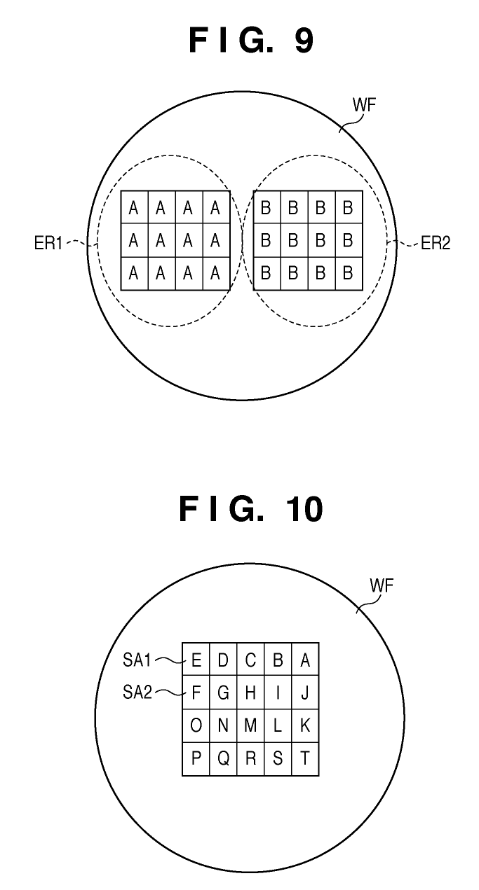

Consider a case in which the substrate WF includes areas which are exposed to light under different exposure conditions. As shown in FIG. 9, assume that exposure processing is performed in an area ER1 under an exposure condition A, and exposure processing is performed in an area ER2 under an exposure condition B. In this case, the correction unit 51 obtains a contact time for the exposure condition A for the area ER1 on the basis of the exposure condition A. The correction unit 51 obtains a contact time for the exposure condition B for the area ER2 on the basis of the exposure condition B. The correction unit 51 corrects the amount of exposure light for each shot area included in the area ER1 on the basis of the contact time for the exposure condition A. The correction unit 51 then corrects the amount of exposure light for each shot area included in the area ER2 on the basis of the contact time for the exposure condition B.

Consider a case in which the respective shot areas in the substrate WF are exposed to light under different exposure conditions. As shown in FIG. 10, assume that settings have been made to perform exposure processing in a shot area SA1 under an exposure condition E and to perform exposure processing in a shot area SA2 under an exposure condition F. In this case, the correction unit 51 obtains a contact time for the exposure condition E for the shot area SA1 on the basis of the exposure condition E. The correction unit 51 obtains a contact time for the exposure condition F for the shot area SA2 on the basis of the exposure condition F. The correction unit 51 then corrects the amount of exposure light for the shot area SA1 on the basis of the contact time for the exposure condition E. The correction unit 51 corrects the amount of exposure light for the shot area SA2 on the basis of the contact time for the exposure condition F.

Alternatively, the correction unit 51 may correct the amount of exposure light for a shot area as an exposure target on the basis of the offset between the amount of exposure light for a test pattern and the amount of exposure light for a pattern (product circuit pattern) in the shot area as the exposure target. For example, it suffices to obtain in advance the offsets between the test patterns formed on the sample used to decide the information of the first function and the information of the second function in steps S2 and S3 in FIG. 2 and the target patterns exposed to light by the exposure processing shown in FIG. 3. In this case, in step S13 in FIG. 3, on the basis of the offset between the test pattern and the target pattern the correction unit 51 further corrects the correction value for the amount of exposure light for each shot area, which is obtained based on the predicted line width, the target line width, and the second function information. This can further reduce variations in the line width of the obtained pattern.

A method of manufacturing a device according to the preferred embodiment of the present invention is suitable for the manufacture of devices (e.g., a semiconductor device and liquid crystal device). This method can include a step of exposing a substrate coated with a photoresist to light by using the above exposure apparatus, and a step of developing the substrate exposed in the exposing step. In addition to the above steps, the method of manufacturing a device can include other known steps (e.g., film forming, doping, etching, resist removing, dicing, bonding, and packaging steps). A device is manufactured through these steps.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2007-240178, filed Sep. 14, 2007, which is hereby incorporated by reference herein in its entirety.

What is claimed is:

1. An exposure apparatus which includes a projection optical system configured to project light from an original onto a substrate and performs an exposure of the substrate to light via a liquid that fills a gap between a final optical element of the projection optical system and the substrate, the apparatus comprising
a controller configured so that
1) an exposure condition for the substrate is input to the controller, the exposure condition including a shot area layout and a dose for a shot area, and
2) the controller obtains a contact time during which the shot area is to be kept in contact with the liquid based on the input exposure condition, and corrects the input dose based on the obtained contact time.

2. An apparatus according to claim 1, wherein
the controller is configured to predict a line width of a pattern to be obtained via the exposure based on the obtained contact time, and to correct the input dose based on the predicted line width.

3. An apparatus according to claim 2, wherein
the controller is configured to predict the line width further based on a previously obtained first function that indicates a relationship between a time during which the shot area is kept in contact with the liquid and a line width of a pattern obtained via the exposure.

4. An apparatus according to claim 2, wherein
the controller is configured to correct the input dose based on a second function that indicates a relationship between a line width of a pattern obtained via the exposure and a dose, the predicted line width, and a target line width.

5. An apparatus according to claim 1, wherein
the controller is configured to determine a cleaning timing for the final optical element based on an accumulated value of the contact time.

6. An apparatus according to claim 3, wherein
the first function is obtained using a test pattern, and
the controller is configured to correct the input dose further based on a previously obtained offset between a dose for the test pattern and a dose for a pattern to be transferred to the shot area.

7. An apparatus according to claim 4, wherein
the second function is obtained using a test pattern, and
the controller is configured to correct the input dose further based on a previously obtained offset between a dose for the test pattern and a dose for a pattern to be transferred to the shot area.

8. A method of manufacturing a device, the method comprising:
exposing a substrate to light using an exposure apparatus defined in claim 1;
developing the exposed substrate; and
processing the developed substrate to manufacture the device.
